(19) United States
(12) Patent Application Publication
(10) Pub. No.: US 2013/0099945 A1
(43) Pub. Date: Apr. 25, 2013

(54) WIRELESS INPUT DEVICE AND KEY-SHAPED RECEIVER THEREOF

(71) Applicant: Hai-Nan SHEN, Dong Guan City (CN)

(72) Inventor: Hai-Nan SHEN, Dong Guan City (CN)

(73) Assignees: LITE-ON TECHNOLOGY CORPORATION, Taipei City (TW); SILITEK ELECTRONIC (GUANGZHOU) CO., LTD., Guangzhou (CN)

(21) Appl. No.: 13/546,811

(22) Filed: Jul. 11, 2012

(30) Foreign Application Priority Data
Oct. 20, 2011 (CN) 201120400829.2

(51) Int. Cl. H03M 11/00

(52) U.S. Cl. 341/22

(57) ABSTRACT

A wireless input device includes a top housing and a receiver. The top housing has an accommodating slot concavely formed thereon. The receiver has a receiving circuit module and an electrical connector arranged beneath the receiving circuit module. The electrical connector is detachably arranged in the accommodating slot. A key-shaped receiver which includes a key cap, a receiving circuit module arranged adjacent to a bottom side of the key cap, and an electrical connector electrically connected to the receiving circuit module.

### BACKGROUND OF THE INVENTION

### FIELD OF THE INVENTION

The instant disclosure relates to a wireless input device and a key-shaped receiver thereof; in particular, to a wireless input device having a key-shaped receiver for wireless communication with the computer.

### DESCRIPTION OF RELATED ART

The wireless input device utilized commonly in recent days such as the wireless keyboard, requires a receiver connected to the computer for wireless communication. The majority of the conventional receivers are arranged individually packaged, this not only increases the chances for the receivers to get lost, but also results in pairing confusions during production.

Conventionally, the receivers are accommodated in the base portion of the wireless input device. Such method requires an accommodating slot to be formed on the base of the wireless input device. This type of arrangement simply reduces the aesthetics of the base of the wireless input device, and the users also have to flip the wireless input device over in order to extract the receiver, bringing about utilization inconvenience.

To address the above issues, the inventor strives via industrial experience and academic research to present the instant disclosure, which can effectively improve the limitations described above.

### SUMMARY OF THE INVENTION

The object of the instant disclosure is to provide a wireless input device and a key-shaped receiver thereof, where the key-shaped receiver is fixed to the top portion of the wireless input device, along with other function keys.

In order to achieve the aforementioned object, the instant disclosure provides a wireless input device, comprising a top housing and a receiver. The top housing has an accommodating slot concavely formed thereon. The receiver has a key cap, a receiving circuit module and an electrical connector arranged on the base portion of the receiving circuit module. The receiving circuit module is arranged adjacent to a bottom side of the key cap. The electrical connector is detachably received by the accommodating slot.

In order to achieve the aforementioned object, the instant disclosure provides a key-shaped receiver which includes a key cap, a receiving circuit module arranged in the key cap, and an electrical connector electrically connected to the receiving circuit module.

The instant disclosure provides the following advantages. No additional packaging is required by the receiver, and the receiver need not be arranged on the base portion of the wireless input device. In other words, no additional retaining slot or retaining mechanism is required to be provided on the base portion of the wireless input device to secure the receiver. In addition, the user can extract the receiver directly from the top portion of the wireless input device, without flipping the wireless input device over to obtain the receiver.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a three-dimensional exploded view of a wireless input device in accordance with the instant disclosure;

FIG. 2 shows a partially-enlarged view of the wireless input device in accordance with the instant disclosure;

FIG. 2A shows a three-dimensional exploded view of a wireless input device in accordance with another embodiment of the instant disclosure;

FIG. 2B shows a three-dimensional exploded view of a wireless input device in accordance with third embodiment of the instant disclosure;

FIG. 3 shows a three-dimensional assembled view of the wireless input device in accordance with the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objects and advantages related to the instant disclosure will be illustrated in the subsequent descriptions and appended drawings.

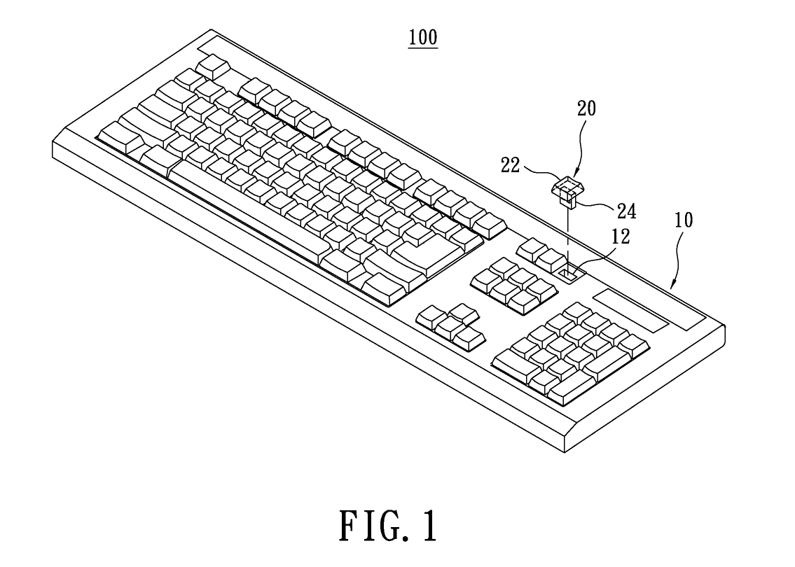

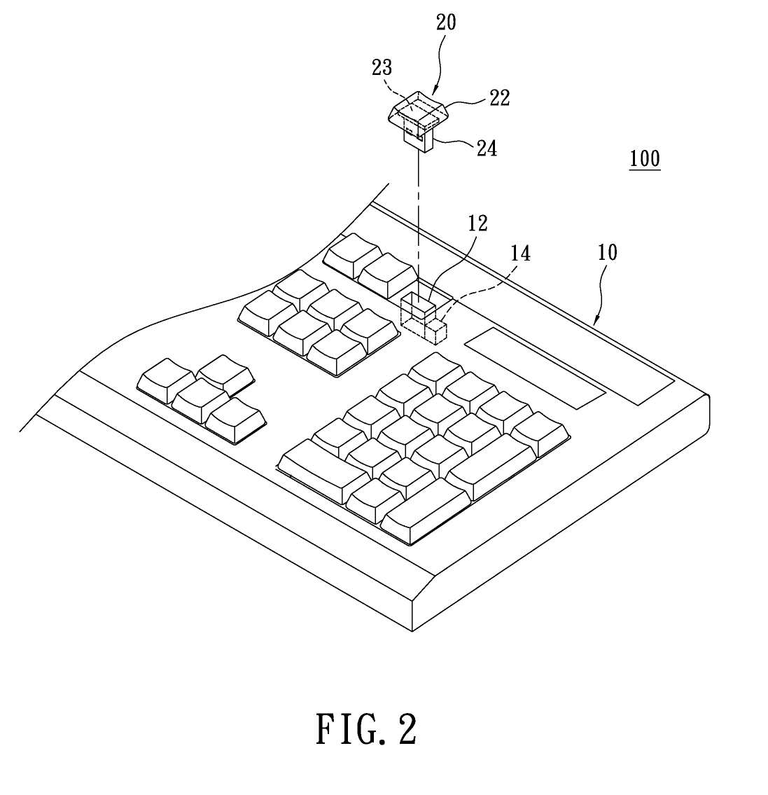

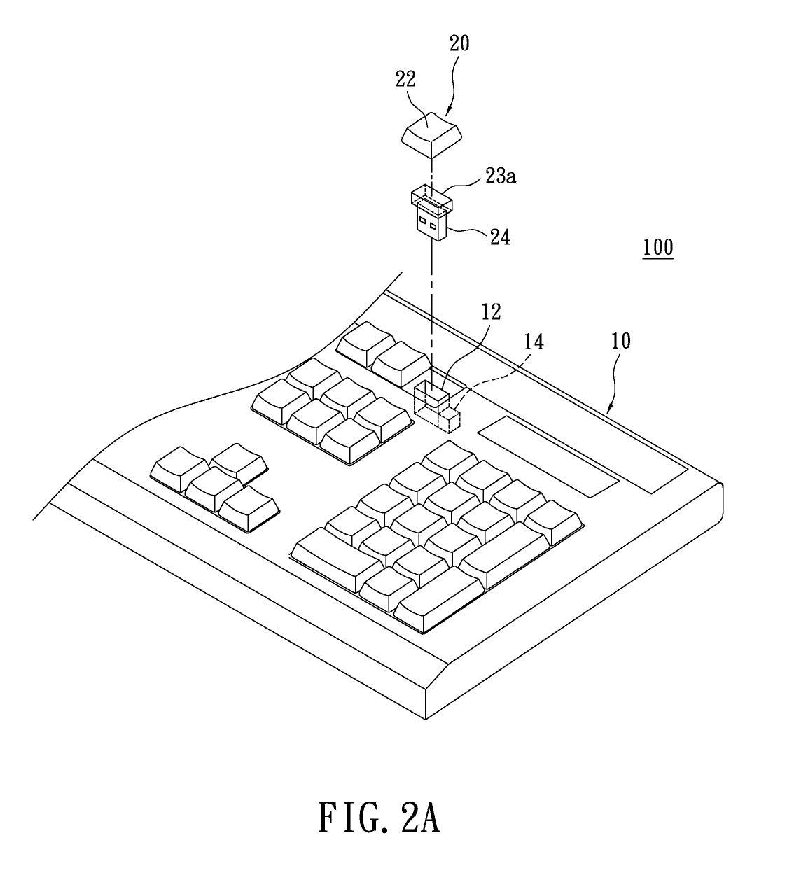

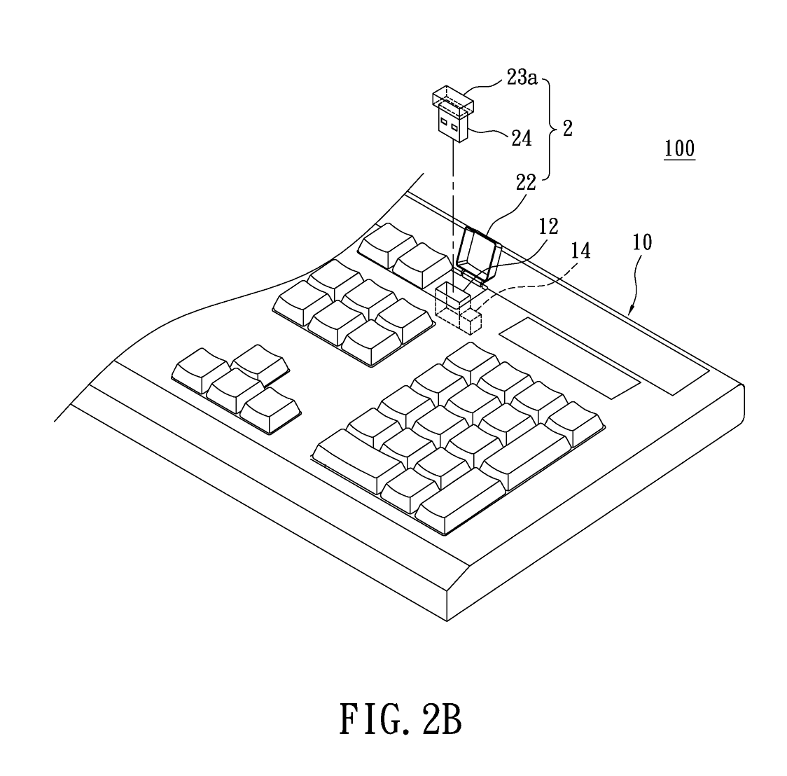

Referring to FIGS. 1-2 which show a three-dimensional and a partially-enlarged view of a wireless input device in accordance with the instant disclosure, respectively. The instant disclosure provides a wireless input device 100 having a key-shaped receiver 20, where the wireless input device 100 is a standard keyboard, but is not restricted thereto. The instant disclosure is applicable to any wireless input device which has keys.

The wireless input device 100 includes a top housing 10 and a receiver 20. The top portion of the top housing 10 has a plurality of keys arranged thereon, and an accommodating slot 12 is concavely formed on the top portion of the top housing 10. The receiver 20 has a key cap 22, a receiving circuit module 23 arranged adjacent to a bottom side of the key cap 22, and an electrical connector 24 electrically connected to the receiving circuit module 23. The electrical connector 24 is detachably received by the accommodating slot 12. The receiving module 23 mainly includes a circuit board and electrical components arranged thereon, such as the microprocessor control unit (MCU), the Radio Frequency Integrated Circuit (RFIC), and the memory device utilized to receive and send signals wirelessly.

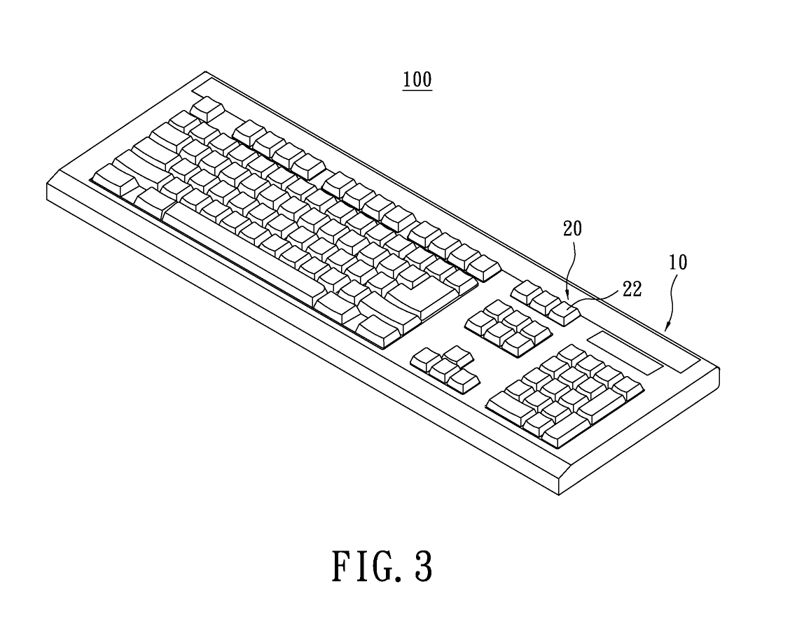

The receiving circuit module 23 can be fixedly arranged in the key cap 22. To provide further illustrations, the receiving circuit module 23 is enclosed in the key cap 22, and is electrically connected to the electrical conductor 24. The key cap 22 can be a common character key, a hot key, an additionally arranged key, or a replacement for less often used hot key. Furthermore, the hot keys, also known as quick keys, refer to specific keys for accomplishing particular commands. Some examples are Fn keys from F1 to F12, the e-mail key, the browse key, the play key and so on. The common character keys refer to the keys excluding the hot keys, which include the character keys, the numeric keys, the note keys and so on, and it is not limited to by this. The receiver 20 of the instant disclosure is arranged on the top portion of the keyboard and disguised in a key-shaped structure, such that the outer appearance of the receiver 20 does not distinct from other keys of the keyboard in any aspect (shown in FIG. 3).

The instant disclosure provides the following advantages. No additional packaging is required by the receiver 20, and the receiver 20 need not be arranged on the base portion of the wireless input device 100. In other words, no additional retaining slot or retaining mechanism is required to be provided on the base portion of the wireless input device 100 to retain the receiver 20. In addition, the user can extract the receiver 20 instantly without flipping the wireless input device 100 over. During the process of production, the receiver 20 can be inserted directly into the corresponding accommodating slot 12 to avoid the risk of being lost, as well as reducing the packaging procedures.

The wireless input device 100 of the instant embodiment can further include a micro switch 14 for power disconnection, which is arranged adjacent to the accommodating slot 12. The receiver 20 establishes contact with the micro switch for power disconnection when inserted into the accommodating slot 12, thereby enabling the power supply of the wireless input device 100 to be cut off for energy saving purposes. In other words, whenever the receiver 20 is stored in the keyboard implies that the keyboard is not under operation. Therefore, a micro switch 14, which is activated by the receiver 20, can be arranged within to cut off the power supply to the keyboard automatically to reduce energy consumption.

With reference to FIG. 2A, which shows an exploded view of another embodiment of a wireless input device in accordance with the instant disclosure. The difference between the instant embodiment and the preceding embodiment is that the key cap 22 and the receiving circuit module 23a are detachable. The receiving circuit module 23a and the electrical connector 24 are similar to present receivers, where the receiving circuit module 23a can be fixed directly in the key cap 22, for example an adhering manner or an engaged manner. Such structure provides the advantage such as no additional mold for the key cap 22 is required.

Please refer to FIG. 2B, which shows an exploded view of third embodiment of a wireless input device in accordance with the instant disclosure. In this embodiment, the key cap 22 is not required to connect to the receiving circuit module 23a. The key cap 22 has a shape like a common key cap, and has one side connected to the top housing 10 adjacent to the accommodating slot 12. Therefore, the key cap 22 like a lid and is arranged on the top portion of the top housing 10 in a turnable way, and the receiver 20 can be extracted by lifting the lid-like key cap 22. The connecting way of the key cap 22 and the top housing 10 could be integrally formed during molding or a pivotal connecting structure.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A wireless input device, comprising:
a top housing having an accommodating slot concavely formed thereon; and
a receiver having a key cap, a receiving circuit module arranged adjacent to a bottom side of the key cap, and an electrical connector electrically connected to the receiving circuit module, wherein the electrical connector is detachably arranged in the accommodating slot.

2. The wireless input device according to claim 1, wherein the wireless input device is a keyboard.

3. The wireless input device according to claim 1, wherein the key cap is a common character key or a hot key.

4. The wireless input device according to claim 1, wherein the receiving circuit module is fixedly arranged and enclosed in the key cap.

5. The wireless input device according to claim 1, wherein the key cap and the receiving circuit module are detachable.

6. The wireless input device according to claim 5, wherein a side of the key cap is connected to the top housing.

7. The wireless input device according to claim 1, further comprising a micro switch for power disconnection arranged adjacent to the accommodating slot, wherein the receiver establishes contact with the micro switch when inserted into the accommodating slot.

8. A key-shaped receiver, comprising:
a key cap;
a receiving circuit module arranged in the key cap; and
an electrical connector electrically connected to the receiving circuit module.

9. The key-shaped receiver according to claim 8, wherein the key cap is a common character key or a hot key.
